(19) United States
(12) Patent Application Publication
(10) Pub. No.: US 2016/0104662 A1
(43) Pub. Date: Apr. 14, 2016

(54) METHOD AND SYSTEM FOR EXTENDING DIE SIZE AND PACKAGED SEMICONDUCTOR DEVICES INCORPORATING THE SAME

(71) Applicant: SEMICONDUCTOR COMPONENTS INDUSTRIES, LLC, Phoenix, AZ (US)

(72) Inventors: Atapol Prajuckamol, Klaeng (TH); Jin Yoong Liong, Seremban (MY); Kai Chat Tan, Tangkak (MY)

(73) Assignee: SEMICONDUCTOR COMPONENTS INDUSTRIES, LLC, Phoenix, AZ (US)

(21) Appl. No.: 14/509,686

(22) Filed: Oct. 8, 2014

(51) Int. Cl. H01L 23/495; H01L 21/78; H01L 23/00; H01L 23/31; H01L 21/56

(52) U.S. Cl. CPC H01L 23/49503; H01L 23/49541; H01L 23/3107; H01L 21/565; H01L 24/83; H01L 21/78; H01L 24/96; H01L 24/97; H01L 2224/83851; H01L 2224/32245

(57) ABSTRACT

A packaged semiconductor device includes a die flag and a plurality of lead frame fingers each having a proximate end spaced apart from the die flag. A first surface of a spacer mechanically and electrically couples to a first surface of the die flag, and a first surface of a die mechanically and electrically couples to a second surface of the spacer. At least one electrical connector electrically couples an electrical contact on a second surface of the die with a lead frame finger. A molding compound encapsulates the die, spacer, at least a portion of the at least one electrical connector, at least a portion of the die flag, and at least a portion of each lead frame finger. A width of the spacer along the second surface of the spacer is greater than a width of the die flag along the first surface of the die flag.

### BACKGROUND

1. Technical Field

Aspects of this document relate generally to packaged semiconductor devices.

2. Background Art

Semiconductor devices are often encased within (or partly within) a package prior to use. Some packages contain a single die while others contain multiple die. The package often offers some protection to the die, such as from corrosion, impact and other damage, and often also includes electrical leads or other components which connect the electrical contacts of the die with a motherboard. The package may also include components configured to dissipate heat from the die into a motherboard or otherwise away from the package.

### SUMMARY

Implementations of packaged semiconductor devices may include: a die flag and a plurality of lead frame fingers, a proximate end of each lead frame finger spaced apart from the die flag; a spacer mechanically and electrically coupled to a first surface of the die flag at a first surface of the spacer; a die mechanically and electrically coupled to a second surface of the spacer at a first surface of the die; at least one electrical connector electrically coupling at least one electrical contact on a second surface of the die with at least one of the lead frame fingers; and a molding compound encapsulating the die, the spacer, at least a portion of the at least one electrical connector, at least a portion of the die flag, and at least a portion of each of the lead frame fingers; wherein a width of the spacer along the second surface of the spacer is greater than a width of the die flag along the first surface of the die flag.

Implementations of packaged semiconductor devices may include one, all, or any of the following:

The first surface of the die flag may be on a side of the die flag opposite a second surface of the die flag, the first surface of the spacer may be on a side of the spacer opposite the second surface of the spacer, and the first surface of the die may be on a side of the die opposite the second surface of the die.

Each lead frame finger may be spaced apart from the die flag by a gap width and the spacer may extend beyond each gap width and over each lead frame finger.

The proximate end of each lead frame finger may be below the spacer.

The first surface of the die flag and a first surface of each of the lead frame fingers may be substantially coplanar.

The first surface of the die flag and the first surface of each of the lead frame fingers may be substantially coplanar below the spacer.

The spacer may have at least one groove configured to receive an insulative material.

The insulative material may be coupled to the at least one groove between the spacer and at least one of the lead frame fingers.

Implementations of a method for extending die size within a packaged semiconductor device may include: mechanically and electrically coupling a spacer to a first surface of a die flag at a first surface of the spacer, the die flag surrounded by a plurality of lead frame fingers wherein a proximate end of each lead frame finger is spaced apart from the die flag; mechanically and electrically coupling a die to a second surface of the spacer at a first surface of the die; and one of overmolding and encapsulating, using one of a molding compound and an encapsulating compound, respectively, the die, the spacer, at least a portion of the die flag and at least a portion of each lead frame finger; wherein a width of the spacer along the second surface of the spacer is greater than a width of the die flag along the first surface of the die flag.

Implementations of a method for extending die size within a packaged semiconductor device may include one, all, or any of the following:

Each lead frame finger may be spaced apart from the die flag by a gap width, and the spacer may extend beyond each gap width and over each lead frame finger.

The proximate end of each lead frame finger may be below the spacer.

The first surface of the die flag may be substantially coplanar with a first surface of each lead frame finger.

The die may be electrically and mechanically coupled to the spacer using a conductive adhesive.

An insulative material may be coupled between the spacer and at least one of the lead frame fingers.

Coupling the insulative material between the spacer and at least one of the lead frame fingers may include coupling the insulative material to a groove in the first surface of the spacer.

A width of the die along the first surface of the die may be greater than the width of the die flag along the first surface of the die flag.

Each lead frame finger may be spaced apart from the die flag by a gap width, and the die may extend beyond each gap width and over each lead frame finger.

The proximate end of each lead frame finger may be below the die.

Implementations of a method of forming a packaged semiconductor device having an extended die size may include: contacting a die flag with an adhesive of an adhesive tape; contacting a plurality of lead frame fingers with the adhesive; mechanically and electrically coupling an electrically conductive spacer to a first surface of the die flag at a first surface of the spacer; mechanically and electrically coupling a die to a second surface of the spacer at a first surface of the die, wherein a width of the die along the first surface of the die is greater than a width of the die flag along the first surface of the die flag; electrically coupling at least one electrical contact on a second surface of the die with at least one of the lead frame fingers using at least one electrical connector; one of overmolding and encapsulating, using one of a molding compound and an encapsulating compound respectively, the die, at least a portion of the at least one electrical connector, the spacer, at least a portion of the die flag, and at least a portion of each lead frame finger to form a packaged semiconductor device; and removing the packaged semiconductor device from the adhesive.

Implementations of a method of forming a packaged semiconductor device having an extended die size may include one, all, or any of the following:

The method may include singulating the packaged semiconductor device.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a front-bottom perspective view of a packaged semiconductor device formed using methods and systems for extending die size;

FIG. 2 is a front-top perspective view of the packaged semiconductor device of FIG. 1;

FIG. 3 is a cross-section view of a spacer of the packaged semiconductor device of FIG. 2 taken along line 1-1;

FIG. 4 is a cross-section view of a spacer and insulative material of the packaged semiconductor device of FIG. 2 taken along line 1-1;

FIG. 5 is a cross-section view of various elements of the packaged semiconductor device of FIG. 2, taken along line 1-1, and an adhesive tape;

FIG. 6 is a cross-section view of various elements of the packaged semiconductor device of FIG. 2, taken along line 1-1, and an adhesive tape;

FIG. 7 is a cross-section view of various elements of the packaged semiconductor device of FIG. 2, taken along line 1-1, and an adhesive tape;

FIG. 8 is a cross section view of the packaged semiconductor device of FIG. 2, taken along line 1-1, and an adhesive tape;

FIG. 9 is a cross-section view of the packaged semiconductor device of FIG. 2, taken along line 1-1; and

FIG. 10 is a cross-section, exploded view of various elements of the packaged semiconductor device of FIG. 2, taken along line 1-1.

### DESCRIPTION

This disclosure, its aspects and implementations, are not limited to the specific components, assembly procedures or method elements disclosed herein. Many additional components, assembly procedures and/or method elements known in the art consistent with the intended methods and systems for extending die size and packaged semiconductor devices incorporating the same will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such methods and systems for extending die size and packaged semiconductor devices incorporating the same, and implementing components and methods, consistent with the intended operation and methods.

Definitions: As used herein: “width” refers to a horizontal measurement on a cross section of a packaged semiconductor device (or elements thereof) when the device is situated with lead frame elements at the bottommost position (such as horizontal widths 38 and 22 shown in FIG. 10); “thickness” refers to a vertical measurement taken from a same view, and; “length” refers to a measurement going into (and/or out of) the page.

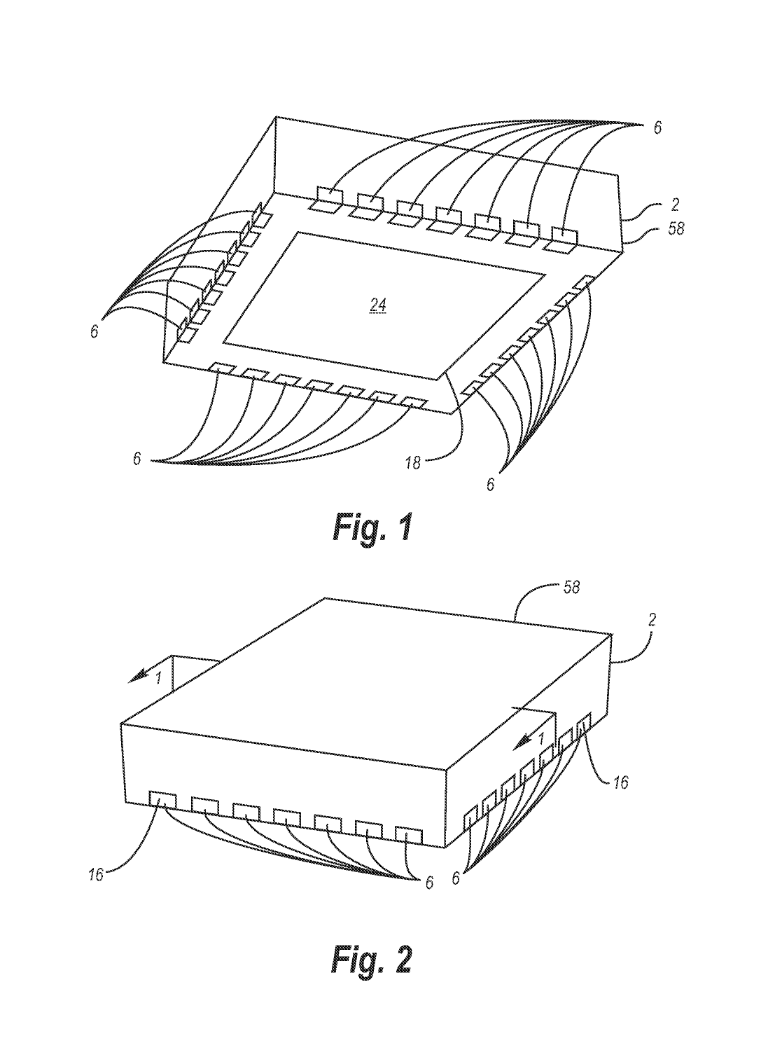

Referring now to FIGS. 1, 2 and 9, a packaged semiconductor device (package) 2 implementation is illustrated that has an extended die size and includes a number of elements at least partially incorporated into and/or covered with a molding or encapsulating compound (compound) 58 with a number of lead frame fingers 6 exposed through the molding compound 58 and a second surface 24 of a die flag 18 also exposed through the molding compound 58. The package 2 of FIGS. 1, 2 and 9 is a quad flat no-leads (QFN) package—in other implementations other types of packages could include an extended die size and/or could be formed using methods of extending a die size as disclosed herein, such as by non-limiting example: a dual flat no leads (DFN) package configuration, a micro lead frame (MLP) configuration, a small-outline no leads (SON) configuration, a small outline integrated circuit (SOIC) configuration, a small outline package (SOP) configuration, a configuration including leads that extend outwardly beyond one or more surfaces of the molding compound 58, such as gull wing leads (as opposed to the versions shown in the drawings wherein the leads are flush, or substantially flush, with the surfaces of the molding compound 58); a quad flat pack (QFP); and other leaded or non-leaded package types that include a leadframe.

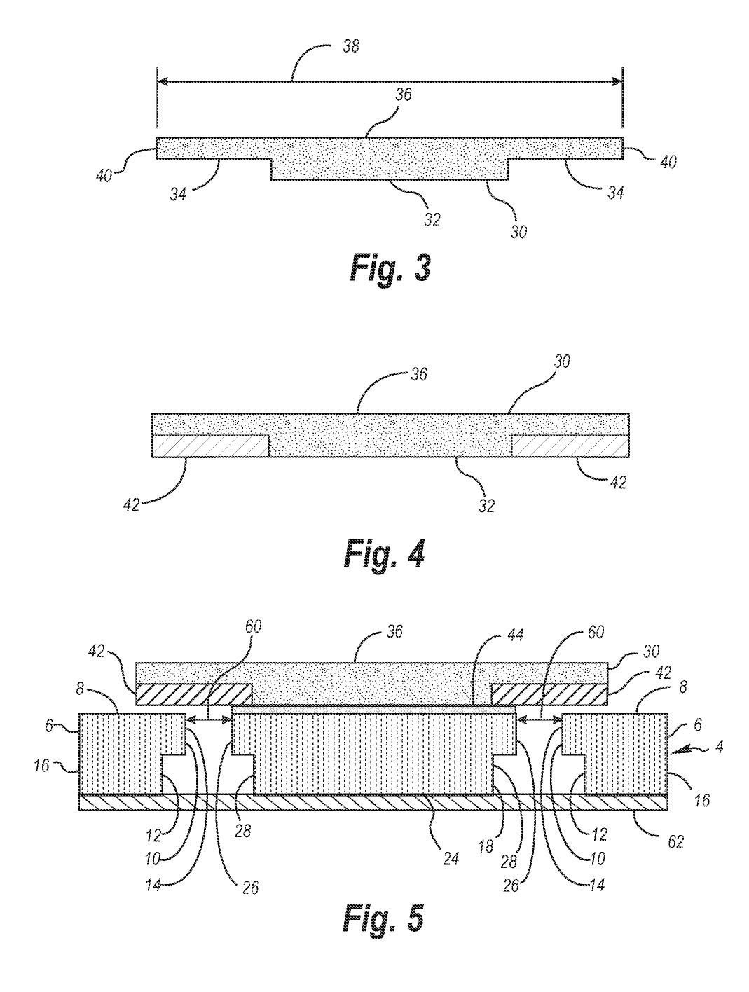

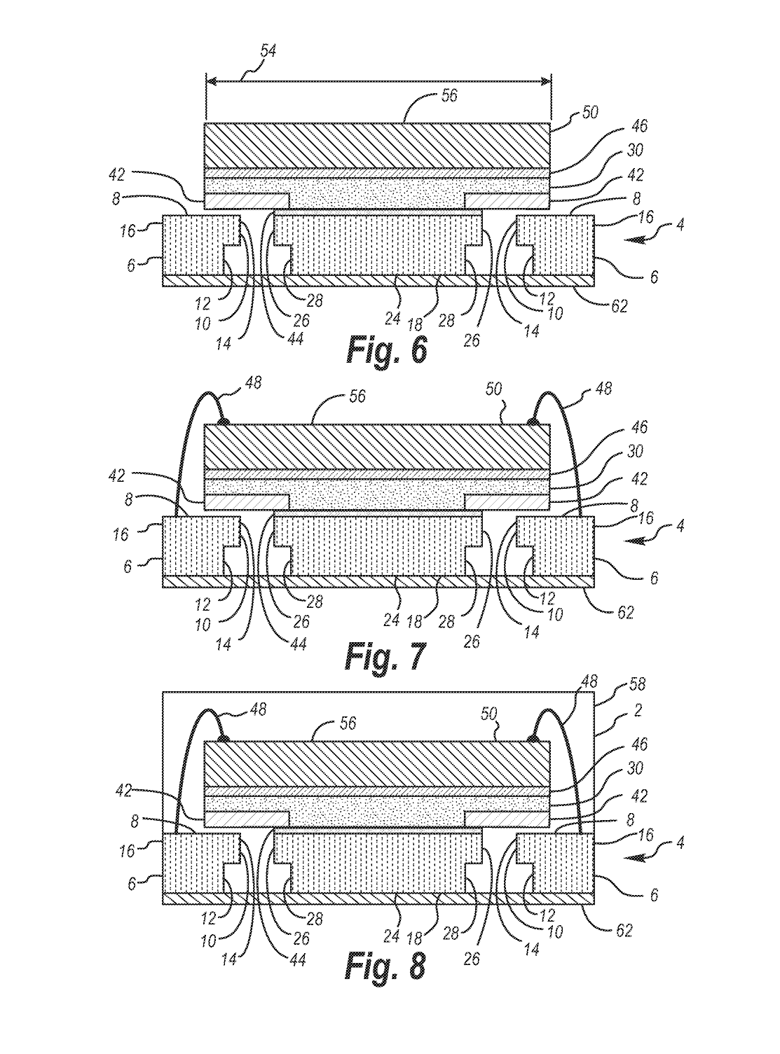

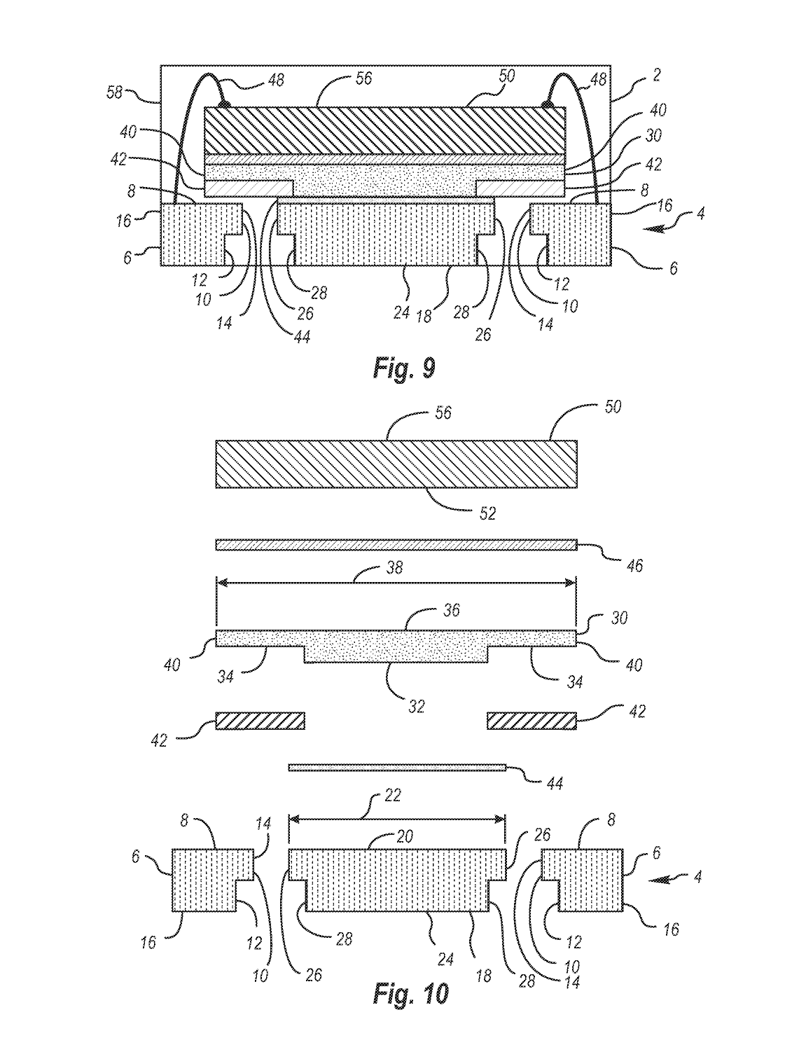

FIG. 1 is a bottom-front perspective view of a package 2 and FIG. 2 is a top-front perspective view of the package 2 of FIG. 1. The distal ends 16 of each lead frame finger 6 are shown exposed on the side surfaces of the package 2 and portions of each lead frame finger 6 are also shown exposed on a bottom surface of the package 2. FIG. 9 is a cross sectional view of the package 2 of FIG. 2 taken along line 1-1. FIGS. 3-8 each illustrate a portion of a method and system for extending die size, and FIG. 10 is a cross sectional exploded view of several of the elements of package 2 of FIG. 9 taken along line 1-1.

Referring now to FIGS. 3-5, in implementations of methods of extending die size, and in packaged semiconductor devices incorporating the same, a lead frame 4 is adhered to an adhesive of an adhesive tape 62. The adhesive tape 62 could be, or could include, by non-limiting example: a map molding support tape sold under the trade name RT SERIES by Hitachi Chemical Co., Ltd. of Tokyo, Japan; a heat resistant tape sold under the trade name PW/TRM series by Nitto Denko Corporation of Osaka, Japan; and the like. In implementations the adhesive tape 62 may be, or may include, a thick tape with low-force ultraviolet (UV) release adhesive such that the lead frame 4 may be removed from the adhesive tape 62 when desired by exposing the adhesive of the adhesive tape 62 to UV light. The adhesive tape 62 may be present and adhered to the lead frame 4 during formation of the package 2 and is removed after molding or encapsulating is completed using a molding or encapsulating compound 58. In instances in which multiple packages 2 are formed on the same strip or piece of adhesive tape 62 the individual packages 2 may be sawed or otherwise singulated prior to or after removal from the adhesive tape 62. Other processing steps not shown in the drawings may also be included, for instance each package 2 may be laser marked, such as, by non-limiting example, on a top or upper surface of the package 2, prior to or after singulation and prior to or after removal from the adhesive tape 62.

The lead frame 4 includes a die flag 18 and a plurality of lead frame fingers 6. In implementations in which multiple die flags 18 included in a single lead frame 4, there are a plurality of lead frame fingers 6 associated with each die flag 18. The die flag 18 in various implementations has a rectangular shape when viewed from above and is surrounded on all four sides by a plurality of lead frame fingers 6. Each lead frame finger 6 is spaced apart from the die flag 18 by a gap width 60. Referring now to FIG. 10, the die flag 18 includes a first surface 20, a second surface 24, a width 22 along the first surface 20, and a plurality of side surfaces 26. In FIG. 10 two side surfaces 26 are shown, though a three-dimensional view would reveal that the die flag 18 actually has four side surfaces 26. One or more of the side surfaces 26 may include a depression (groove) 28 which functions as a mold lock to secure the die flag 18 and/or other components of the package 2 within the compound 58 after molding or encapsulation. In FIG. 10 two depressions 28 are shown which may be used for a mold lock, and in implementations one, two, three, or four side surfaces 26 of the die flag 18 could include depressions 28 to form a mold lock. In other implementations a mold lock could be absent, and there could be no depressions 28 in any of the side surfaces 26.

Referring to FIGS. 1, 2, 5 and 10, each lead frame finger 6 has a first surface 8 and one or more side surfaces 10. A proximate end 14 of each lead frame finger 6 is spaced apart from the die flag 18 by a gap width 60, and a distal end 16 of each lead frame finger 6 is configured to be exposed through the compound 58 after molding or encapsulation to provide electrical communication between electrical components of a die 50 and other electrical components of the die 50 and/or elements external to the die 50. In the implementations shown a bottom surface of each lead frame finger 6 is also configured to be exposed through the compound 58 after molding, for similar purposes, though in other implementations a package could be formed which exposes only the bottom surface or only the side surfaces of the distal ends 40, and so forth, according to the design of an element or location of a printed circuit board (PCB) (motherboard) configured to receive and be electrically and mechanically coupled to the package.

Referring to FIG. 10, each lead frame finger 6 has a side surface 10 at the proximate end 14 in which a depression 12 is present to be used for a mold lock to secure the lead frame finger 6 and/or other components within the compound 58 after molding or encapsulation. In FIG. 10 one depression 12 is shown on each lead frame finger 6 though, in implementations, a three dimensional view may reveal one, two, three or four depressions 12 on each lead frame finger 6, such as each on a different side surface, to provide a mold lock for each lead frame finger 6. In other implementations a mold lock could be absent, and there could be no depressions 12 in any of the side surfaces 10 or other surfaces of the lead frame finger 6.

The portion of the side surface 10 above the depression 12, which does not include the depression 12, is a flange, and the portion of the side surface 26 which is above the depression 28, which does not include the depression 28, is also a flange. Accordingly, although the depressions 12, 28 are described above as providing the ability to mold lock the lead frame fingers 6, die flag 18 and/or the overall package 2, it could equally be stated that it is the flanges that provide this ability. Similarly, as it is indicated above that the depressions 12, 28 may be included on one, two, three or four sides of each respective component, or altogether excluded, likewise the flanges may be included on one, two, three or four sides of the die flag 18 and/or lead frame fingers 6, respectively, or altogether excluded.

In the implementations shown the lead frame fingers 6 and die flag(s) 18 are incorporated into a single lead frame 4. In other implementations, the die flag(s) 18 and lead frame fingers 6 may be provided using two or more lead frames during the formation of each package 2.

As shown in FIG. 10, in implementations the first surface 20 of the die flag 18 and the first surface 8 of each lead frame finger 6 are located in the same plane, or in other words, are coplanar. Referring to FIG. 9, the first surface 20 and first surface 8 are in the same plane, or are coplanar, below a spacer 30 and below a die 50, during fabrication of the package 2 and after fabrication is complete. In various implementations, the first surface 20 and first surface 8 of each lead frame finger 6 may be substantially coplanar, though not exactly coplanar.

In the implementations shown the first surface 20 of the die flag 18 is on a side of the die flag 18 opposite the second surface 24 of the die flag 18—the first surface 20 being an upper or top surface and the second surface 24 being a bottom or lower surface—and the first surface 8 of each lead frame finger 6 is on an upper or top surface opposite a bottom or lower surface on an opposite side of the lead frame finger 6. Accordingly, in methods and systems for extending die size, and in packages incorporating the same, adhering the lead frame 4 to an adhesive or adhesive surface of the adhesive tape 62 includes adhering the second surface 24 of the die flag 18 and a bottom surface of each lead frame finger 6 to the adhesive of the adhesive tape 62. The lead frame 4, including die flag(s) 18 and lead frame fingers 6, may be formed of metals, having metallic coatings (or not), as desired, and/or may be made of materials conventionally used, or hereafter discovered, for creating lead frames.

Referring to FIGS. 3-5 and 10, in various implementations, a spacer 30 is provided which includes a first surface 32 on a bottom or lower surface, a second surface 36 on an upper or top surface located on a side of the spacer 30 opposite the side of the first surface 32, and distal ends 40 at the sides of the spacer 30. The spacer 30 has a width 38 along the second surface 36. A groove 34 is included in the first surface 32 which serves to separate the spacer 30 from the lead frame fingers 6 when the spacer 30 is coupled to the die flag 18 (as shown in FIG. 5), so that the spacer 30 is not in electrical communication with any of the lead frame fingers 6. An insulative material 42 may, as in the implementation illustrated, also be placed in the groove 34 to further ensure that there is no electrical connection/coupling/arcing between the spacer 30 and the lead frame fingers 6, though in other implementations the insulative material 42 could be omitted altogether and the groove 34 could be sufficient to ensure that there is no electrical communication between the spacer 30 and lead frame fingers 6. In implementations in which the insulative material 42 is included, the insulative material 42 may be, or may include, by non-limiting example, any material conventionally used as a wafer backside coating (WBC) material, and/or one or more of the following nonconductive die attach adhesives sold under the following trade names by Henkel AG & Co. KGaA of Dusseldorf, Germany (hereinafter “Henkel”): ABLESTIK ABLECOAT 8006NS or LOCTITE ABLESTIK ABLECOAT 8006NS (WBC); ABLEBOND 2025DSI; ABLEBOND 8900NC; HYSOL QMI547; HYSOL QMI536HT; HYSOL QMI538NB; ABLECOAT 8008NC (WBC), and/or ABLESTIK ABP-8910T. The insulative material 42 may have any of the properties, and may be applied using techniques disclosed in, Appendix A, hereby incorporated herein entirely by reference.

Although the cross sectional views in the figures show the spacer 30 as appearing to have two grooves 34, a three dimensional view of the implementation shown would reveal that the spacer 30 when viewed from the bottom has a rectangular, substantially rectangular, square, or substantially square shape, and that the groove 34 is thus along each of four edges of the rectangle or square shape of the spacer 30 and forms, therefore, one continuous groove having the shape of a rectangle or square. The spacer 30 is formed of an electrically conductive material, such as a metal or metal alloy, and electrically couples a die 50 with the die flag 18. As seen in the drawings, within the package 2 the die 50 is electrically coupled to the die flag 18 only via or through the spacer 30.

The first surface 32 of the spacer 30 is mechanically and electrically coupled to the first surface 20 of the die flag 18. In the implementations shown this is done with a conductive adhesive 44. In other implementations other mechanisms could be used, such as soldering with a solder paste. In implementations in which conductive adhesive 44 is used the conductive adhesive 44 could be or could include, by non-limiting example, one or more adhesives sold under the following trade names by Henkel: ABLEBOND FS849-TI; ABLECOAT 8008HT (WBC); ABLETHERM 2600AT, ABLEBOND 84-1LMISR4; ABLEBOND 84-1LMISR8; ABLEBOND 3230; ABLESTIK 8008MD (WBC); ABLEBOND 8200C; ABLEBOND 8200TI; ABLEBOND 8290; ABLEBOND 8352L; HYSOL QMI519; HYSOL QMI529HT-LV, and/or; HYSOL QMI529HT. In implementations in which a solder or solder paste is used, the solder could be, or could include, by non-limiting example, one or more of the following solders sold under the following trade names by Henkel: MULTICORE DA100, and/or; MULTICORE DA101.

Referring to FIGS. 3-5, the insulative material 42 may be such that its bottom surface is flush with, or is substantially flush with, the first surface 32. The conductive adhesive 44 may dry, cure or otherwise solidify in such a way between the spacer 30 and the die flag 18 that it provides a thickness between these elements so that the insulative material 42 does not physically contact the lead frame fingers 6, as illustrated in FIG. 5. In other implementations the conductive adhesive 44 could provide negligible thickness between the die flag 18 and spacer 30 such that the insulative material 42 physically contacts the lead frame fingers 6 when the spacer 30 is coupled to the die flag 18.

From FIG. 5 it may be seen that in implementations the spacer 30 is situated over or above the lead frame fingers 6 and, correspondingly, the lead frame fingers 6 are below the spacer 30. “Over” and “above” as used herein are defined as directly over and directly above, respectively, though not necessarily touching. “Under” and “below” as used herein are defined as directly under and directly below, respectively, though not necessarily touching. For example, the conductive adhesive 44, though located higher than the first surfaces 8 of the lead frame fingers 6, is not “over” or “above” the lead frame fingers 6, for purposes of this disclosure. Similarly, the proximate ends 14 of the lead frame fingers 6 are “below” or “under” the insulative material 42, “below” or “under” the spacer 30, “below” or “under” the groove(s) 34, “below” or “under” the conductive adhesive 46, and “below” or “under” the die 50, but not “below” or “under” the conductive adhesive 44.

Referring to FIGS. 5 and 10, the spacer 30 in the implementations shown has a width 38 along its second surface 36 that is greater than a width 22 of the die flag 18 along a first surface 20 of the die flag 18. It can also be seen that, in the implementations shown, width 38 is greater than the sum of width 22 plus two gap widths 60, and accordingly the spacer 30 extends beyond the gap widths 60 and is above, or over, the lead frame fingers 6. In other implementations, the width 38 could be wider than width 22 but not wider than width 22 plus two gap widths 60, and in such implementations the spacer 30 could extend over a portion of each gap width 60 but not beyond the entire gap widths 60 and, accordingly, not over or above the lead frame fingers 6. Width 38 in particular implementations will generally be some amount less than a width measured from the distal end 16 of one lead frame finger 6 to the distal end 16 of an opposing lead frame finger 6 so that there is some portion of the first surface 8 exposed to receive an electrical connector 48 (referring to FIG. 7) to electrically couple electrical components of the die 50 with the lead frame fingers 6. However, in other implementations, width 38 may be the same as the width measured from the distal ends 16 of the lead fingers 6 or greater, depending upon the package type.

Referring now to FIGS. 5, 6 and 10, a first surface 52 of a die 50 is electrically and mechanically coupled to the second surface 36 of the spacer 30. In implementations, this is done with a conductive adhesive 46, though in other implementations it could be accomplished with other mechanisms, such as through soldering with a solder paste. Conductive adhesive 46 could be, or could include, the same or a similar material as conductive adhesive 44. Conductive adhesive 46 could be, or could include, any known or hereafter discovered die attach adhesive, including any conductive epoxy or elastomer, including any of those disclosed in this document. In the implementation shown the die 50 is sized so that its sides extend as far on each side as the distal ends 40 of the spacer 30. In other words, the width 54 of the die 50 along the second surface 56 of the die 50 is equal, in the drawings, with width 38 of the spacer 30. In other implementations the width 54 could be greater than, or less than, width 38.

As can be seen from FIGS. 5, 6 and 10, the width 54 of die 50 along the second surface 56, in the implementations shown, is greater than width 22 of the die flag 18 along a first surface 20 of the die flag 18. It can also be seen that, in the implementations shown, width 54 is greater than the sum of width 22 plus two gap widths 60, and accordingly the die 50 extends beyond the gap widths 60 and is above, or over, the lead frame fingers 6. In other implementations the width 54 could be wider than width 22 but not wider than width 22 plus two gap widths 60, and in such implementations the die 50 could extend over a portion of each gap width 60 but not beyond it and, accordingly, not over or above the lead frame fingers 6. Width 54 in particular implementations will generally be some amount less than a width measured from the distal end 16 of one lead frame finger 6 to the distal end 16 of an opposing lead frame finger 6 so that there is some portion of the first surface 8 exposed to receive an electrical connector 48 (referring to FIG. 7) to electrically couple electrical components of the die 50 with the lead frame fingers 6. However, the width could be the same or greater in particular packaging implementations.

Referring now to FIG. 7, once the die 50 has been secured to the spacer 30, electrical connectors 48 are used to couple electrical contacts on the second surface 56 of the die 50 with the lead frame fingers 6. In the implementations shown electrical connectors 48 are wire bonds, though in other implementations they could be conductive clips or some other electrical connector. The electrical contacts on the second surface 56 of the die 50 could be, by non-limiting example, bumps, bond pads, and the like.

Referring now to FIG. 8, once all of the necessary electrical connectors 48 are in place, the package 2 may be completed by molding or encapsulating the various components using a molding or encapsulating compound 58. It may be seen from FIG. 8 that the molding or encapsulating compound 58 covers or encapsulates the die 50, the spacer 30, the insulative material 42 (if present), the conductive adhesives 44, 46, and a least a portion of the die flag(s) 18 and lead frame fingers 6. The molding or encapsulating compound 58 fills in the space or volume between the die flag 18 and lead frame fingers 6, such as filling in the depressions 12, 28, underneath the flanges, so that when the molding or encapsulating material is dried or otherwise cured or solidified, the package 2 includes mold locks to help retain the various elements within the package 2.

The molding or encapsulating compound 58 could be, or could include, an epoxy resin sold under the trade name G760 SERIES by Sumitomo Bakelite Co., Ltd. of Tokyo, Japan (hereinafter “Sumitomo”). The molding or encapsulating compound 58 could be, or could include, one or more epoxy resins sold under the following trade names by Henkel: HYSOL GR828D; HYSOL GR869; HYSOL KL-G730; HYSOL KL-7000HA; HYSOL KL-G900HC; HYSOL KL-G900HP; HYSOL GR725LV-LS; HYSOL KL-G450H; HYSOL KL-4500-1NT, and/or; HYSOL GR9810 series. The molding or encapsulation process may use methods such as applying the compound 58 in liquid form and then curing, drying or otherwise solidifying the compound 58, and may include dispensing of the compound 58 with a nozzle of a dispensing machine into a mold or filling a mold chase with the compound 58 via injection molding.

Referring to FIGS. 8 and 9, once the molding or encapsulating compound 58 has solidified, the package 2 may be removed from the adhesive tape 62. As discussed somewhat above, if multiple packages 2 are coupled to the same piece of adhesive tape 62, then singulation through sawing or another technique may occur before or after removal of the package(s) 2 from the adhesive tap 62, and additionally laser marking or another marking technique may be used to mark the package(s) 2 before or after singulation and before or after removal of the package(s) 2 from the adhesive tape 62.

In various implementations, one or more of the above mentioned processing steps may be carried out using a pick and place tool such as, by non-limiting example: coupling the first surface 32 of the spacer 30 to the first surface 20 of the die flag 18 and coupling the first surface 52 of the die 50 to the second surface 36 of the spacer 30.

Although the drawings only show examples of a package 2 having a single die 50 therein, in implementations the methods may be used, or additional methods may be included, to form a multi-chip package (multi-die package), or to form a stacked die package, and the like, wherein more than one die 50 is mounted on the spacer 30 and/or wherein there are multiple die flags 18 and/or multiple spacers 30 in each package.

One of the basic and novel characteristics of implementations of methods and systems for extending die size and packaged semiconductor devices incorporating the same disclosed herein is the use of an extended or increased die size, that has a greatest width greater that a greatest width of the die flag, without modifying the structure of the die flag and/or without modifying the structure of the lead frame fingers, and while keeping the top surfaces of the die flag and lead frame fingers in the same plane (or substantially the same plane). One of the basic and novel characteristics of implementations of methods and systems for extending die size and packaged semiconductor devices incorporating the same disclosed herein is the ability to increase the size of a die in a particular package or set of packages without modifying the conventional lead frame(s) used in prior versions of the package.

In places where the description above refers to particular implementations of methods and systems for extending die size and implementing components, sub-components, methods and sub-methods, it should be readily apparent that a number of modifications may be made without departing from the spirit thereof and that these implementations, implementing components, sub-components, methods and sub-methods may be applied to other methods and systems for extending die size.

1. A packaged semiconductor device, comprising:
a die flag and a plurality of lead frame fingers, a proximate end of each lead frame finger spaced apart from the die flag;
a spacer mechanically and electrically coupled to a first surface of the die flag at a first surface of the spacer, the spacer comprising at least one groove with an insulative material coupled thereto, the insulative material located between the spacer and at least one of the plurality of lead frame fingers;
a die mechanically and electrically coupled to a second surface of the spacer at a first surface of the die;
at least one electrical connector electrically coupling at least one electrical contact on a second surface of the die with at least one of the lead frame fingers; and
a molding compound encapsulating the die, the spacer, at least a portion of the at least one electrical connector, at least a portion of the die flag, and at least a portion of each of the lead frame fingers;
wherein a width of the spacer along the second surface of the spacer is greater than a width of the die flag along the first surface of the die flag.

2. The packaged semiconductor device of claim 1, wherein the first surface of the die flag is on a side of the die flag opposite a second surface of the die flag, the first surface of the spacer is on a side of the spacer opposite the second surface of the spacer, and the first surface of the die is on a side of the die opposite the second surface of the die.

3. The packaged semiconductor device of claim 1, wherein each lead frame finger is spaced apart from the die flag by a gap width and wherein the spacer extends beyond each gap width and over each lead frame finger.

4. The packaged semiconductor device of claim 1, wherein the proximate end of each lead frame finger is below the spacer.

5. The packaged semiconductor device of claim 1, wherein the first surface of the die flag and a first surface of each of the lead frame fingers are substantially coplanar.

6. The packaged semiconductor device of claim 5, wherein the first surface of the die flag and the first surface of each of the lead frame fingers are substantially coplanar below the spacer.

7-20. (canceled)
